(19) United States
(12) Patent Application Publication
(10) Pub. No.: US 2023/0382714 A1
(43) Pub. Date: Nov. 30, 2023

(54) MEMS MICROPHONE AND METHOD OF MANUFACTURING THE SAME

(71) Applicant: DB HITEK CO., LTD., Seoul (KR)

(72) Inventors: Min Hyun JUNG, Chungcheongbuk-do (KR); Joo Hyeon LEE, Gyeonggi-do (KR)

(21) Appl. No.: 18/201,710

(22) Filed: May 24, 2023

(30) Foreign Application Priority Data
May 25, 2022 (KR) 10-2022-0064291

(51) Int. Cl. B81B 3/00; B81C 1/00

(52) U.S. Cl. CPC B81B 3/0021; B81C 1/00158; B81B 2201/0257; B81B 2203/0127; B81B 2203/0307; B81B 2203/0315; B81B 2203/0338; B81B 2203/0353; B81B 2203/04; B81C 2201/0154; B81C 2201/014; B81C 2201/0133; B81C 2201/0166; B81C 2201/0164

(57) ABSTRACT

A MEMS microphone includes a substrate having a cavity, a diaphragm disposed above the cavity and having a ventilation path, and a back plate disposed above the diaphragm and having a plurality of air holes. The ventilation path includes a plurality of slits extending in a circumferential direction.

### CROSS-REFERENCE TO RELATED APPLICATION

This application claims the priority benefit of Korean Patent Application No. 10-2022-0064291, filed on May 25, 2022, and all the benefits accruing therefrom under 35 U.S.C. § 119, the contents of which are incorporated by reference in their entirety.

### TECHNICAL FIELD

The present disclosure relates to a MEMS (Micro Electro Mechanical System) microphone and a method of manufacturing the same. More specifically, the present disclosure relates to a MEMS microphone including a diaphragm and a back plate formed using semiconductor processing technology and a method of manufacturing the same.

### BACKGROUND

A MEMS microphone may be manufactured by a semiconductor processing technology and may output a change in capacitance caused by a change in a distance between a diaphragm and a back plate as an electrical signal.

Specifically, the diaphragm may be vibrated by a sound pressure, and as a result, a change in the distance between the diaphragm and the back plate may occur. The diaphragm may include a lower electrode layer, and the back plate may include an upper electrode layer. Accordingly, the capacitance between the lower electrode layer and the upper electrode layer may be changed by the vibration of the diaphragm.

The capacitance may be proportional to areas of the lower electrode layer and the upper electrode layer and inversely proportional to a distance between the lower electrode layer and the upper electrode layer. Therefore, the sensitivity of the MEMS microphone may be improved by increasing the areas of the lower electrode layer and the upper electrode layer. However, there is a limit to increasing the areas of the lower electrode layer and the upper electrode layer when the size of the MEMS microphone is reduced.

In addition, when the size of the MEMS microphone is reduced, the elastic strength of the diaphragm may be increased. In such case, the vibration of the diaphragm due to the sound pressure may be reduced, and thus the sensitivity of the MEMS microphone may be lowered.

### SUMMARY

The present disclosure provides a MEMS microphone with improved sensitivity and a method of manufacturing the same.

In accordance with an aspect of the present disclosure, a MEMS microphone may include a substrate having a cavity, a diaphragm disposed above the cavity and having a ventilation path, and a back plate disposed above the diaphragm and having a plurality of air holes. Particularly, the ventilation path may include a plurality of slits extending in a circumferential direction.

In accordance with some embodiments of the present disclosure, the MEMS microphone may further include a first anchor portion configured to surround the diaphragm and fixing the diaphragm on the substrate. In such case, the diaphragm may include a lower electrode layer made of a conductive material, and a ventilation region disposed between the lower electrode layer and the first anchor portion and through which the slits are formed.

In accordance with some embodiments of the present disclosure, the ventilation path may include inner slits adjacent to the lower electrode layer and extending in the circumferential direction, and outer slits adjacent to the first anchor portion and extending in the circumferential direction.

In accordance with some embodiments of the present disclosure, the ventilation path may further include first intermediate slits disposed between the inner slits and the outer slits and extending in the circumferential direction.

In accordance with some embodiments of the present disclosure, the ventilation path may further include second intermediate slits radially extending and connecting between the inner slits and the outer slits.

In accordance with some embodiments of the present disclosure, the ventilation path may further include third intermediate slits radially extending between the inner slits and the outer slits.

In accordance with some embodiments of the present disclosure, the ventilation path may further include first extending slits radially extending from ends of the inner slits toward the outer slits, and second extending slits radially extending from ends of the outer slits toward the inner slits.

In accordance with some embodiments of the present disclosure, the ventilation path may further include first branch slits radially extending from the inner slits toward the first anchor portion, and second branch slits radially extending from the outer slits toward the lower electrode layer.

In accordance with some embodiments of the present disclosure, the diaphragm may include a plurality of convex portions respectively corresponding to the air holes and protruding toward the back plate.

In accordance with some embodiments of the present disclosure, each of the convex portions may have a hollow truncated cone or hollow truncated pyramid shape.

In accordance with some embodiments of the present disclosure, the back plate may include a plurality of second convex portions configured to surround the air holes, respectively, and protruding in a same direction as the convex portions.

In accordance with some embodiments of the present disclosure, each of the convex portions may have an upper inclined surface, and each of the second convex portions may have a lower inclined surface corresponding to the upper inclined surface.

In accordance with another aspect of the present disclosure, a method of manufacturing a MEMS microphone may include forming a diaphragm having a ventilation path on a substrate, forming a back plate having a plurality of air holes above the diaphragm, and forming a cavity exposing the diaphragm through the substrate. Particularly, the ventilation path may include a plurality of slits extending in a circumferential direction.

In accordance with some embodiments of the present disclosure, forming the diaphragm may include forming a lower insulating layer on the substrate, partially removing the lower insulating layer to form a first anchor channel partially exposing the substrate, forming a lower silicon layer on the lower insulating layer and the first anchor channel, performing an ion implantation process to form a portion of the lower silicon layer into a lower electrode layer, and patterning the lower silicon layer to form the diaphragm and the ventilation path. In such case, the lower silicon layer may be patterned so that the diaphragm includes the lower electrode layer.

In accordance with some embodiments of the present disclosure, a portion of the lower silicon layer formed in the first anchor channel may function as a first anchor portion for fixing the diaphragm on the substrate, and the lower silicon layer may be patterned so that the first anchor portion remains in the first anchor channel.

In accordance with some embodiments of the present disclosure, the ventilation path may be formed through a ventilation region disposed between the lower electrode layer and the first anchor portion.

In accordance with some embodiments of the present disclosure, the diaphragm may be formed to include a plurality of convex portions respectively corresponding to the air holes and protruding toward the back plate.

In accordance with some embodiments of the present disclosure, forming the diaphragm may further include forming a mask layer on the substrate to cover portions where the convex portions are to be formed, performing an etching process using the mask layer as an etching mask to partially remove a surface portion of the substrate, and removing the mask layer. In such case, the lower insulating layer may be formed on the substrate after the mask layer is removed.

In accordance with some embodiments of the present disclosure, forming the back plate may include forming an upper insulating layer on the diaphragm, forming an upper silicon layer on the upper insulating layer, performing an ion implantation process to form a portion of the upper silicon layer into an upper electrode layer, removing another portion of the upper silicon layer to expose a portion of the upper insulating layer, and forming a support layer for supporting the upper electrode layer on the upper electrode layer and the exposed portion of the upper insulating layer.

In accordance with some embodiments of the present disclosure, forming the back plate may further include partially removing the upper insulating layer and the lower insulating layer to form a second anchor channel partially exposing the substrate. In such case, a portion of the support layer formed in the second anchor channel may function as a second anchor portion for fixing the back plate on the substrate.

In accordance with the embodiments of the present disclosure as described above, the ventilation path including the plurality of slits may be formed in the ventilation region. Accordingly, the elastic strength of the diaphragm may be reduced, thereby improving the sensitivity of the MEMS microphone. Further, the diaphragm may include the convex portions corresponding to the air holes formed through the back plate, thereby increasing an area of the lower electrode layer. In addition, the back plate may include the second convex portions corresponding to the convex portions, thereby increasing an area of the upper electrode layer. As a result, the capacitance of the MEMS microphone may be increased, and thus the sensitivity of the MEMS microphone may be significantly improved.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic plan view illustrating a MEMS microphone in accordance with an embodiment of the present disclosure;

FIG. 2 is a schematic cross-sectional view taken along a line II′-II″ as shown in FIG. 1;

FIGS. 3 to 8 are schematic enlarged plan views illustrating examples of a ventilation path as shown in FIG. 2;

FIG. 9 is a schematic cross-sectional view illustrating a MEMS microphone in accordance with another embodiment of the present disclosure; and

FIGS. 10 to 24 are schematic cross-sectional views illustrating a method of manufacturing the MEMS microphone as shown in FIG. 2.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

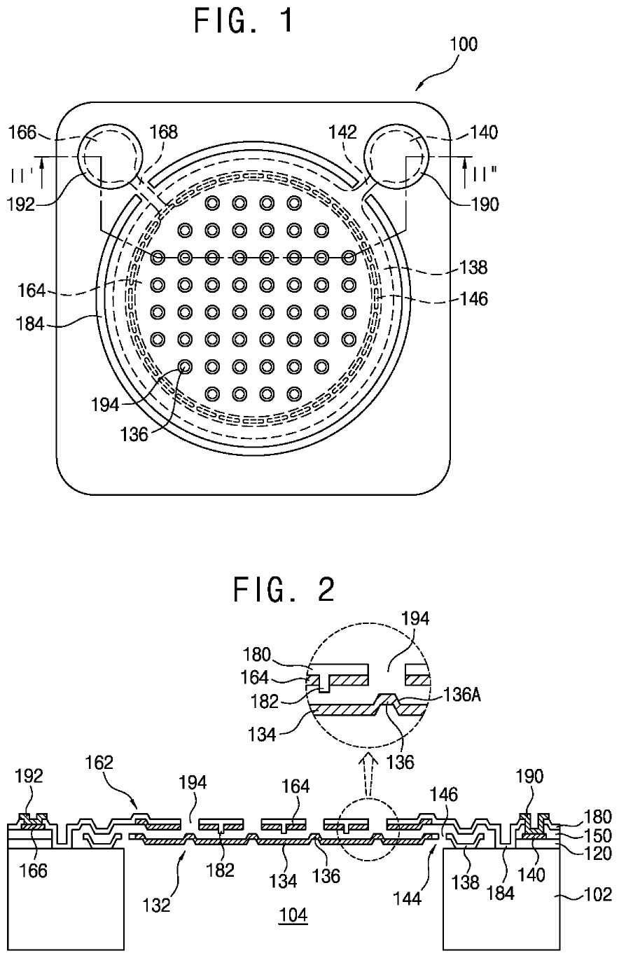

FIG. 1 is a schematic plan view illustrating a MEMS microphone in accordance with an embodiment of the present disclosure, and FIG. 2 is a schematic cross-sectional view taken along a line II′-II″ as shown in FIG. 1.

Referring to FIGS. 1 and 2, a MEMS microphone 100, in accordance with an embodiment of the present disclosure, may include a substrate 102 having a cavity 104, a diaphragm 132 disposed above the substrate 102 to correspond to the cavity 104, and a back plate 162 disposed above the diaphragm 132 and having a plurality of air holes 194. The diaphragm 132 may be disposed above the substrate 102 to cover the cavity 104. The cavity 104 may be formed to pass through the substrate 102, and the diaphragm 132 may be exposed downward through the cavity 104.

In accordance with an embodiment of the present disclosure, the MEMS microphone 100 may include a first anchor portion 138 configured to surround the diaphragm 132 and fixing the diaphragm 132 on the substrate 102. The diaphragm 132 may include a lower electrode layer 134 made of a conductive material. For example, the lower electrode layer 134 may have a disk shape, and the first anchor portion 138 may have a circular ring shape. In addition, the diaphragm 132 may have a ventilation path 146 connecting an air gap between the diaphragm 132 and the back plate 162 with an inner space of the cavity 104. For example, the diaphragm 132 may include a ventilation region 144 having a circular ring shape and disposed between the lower electrode layer 134 and the first anchor portion 138, and the ventilation path 146 may be formed through the ventilation region 144. In particular, the ventilation path 146 may include a plurality of slits extending in a circumferential direction.

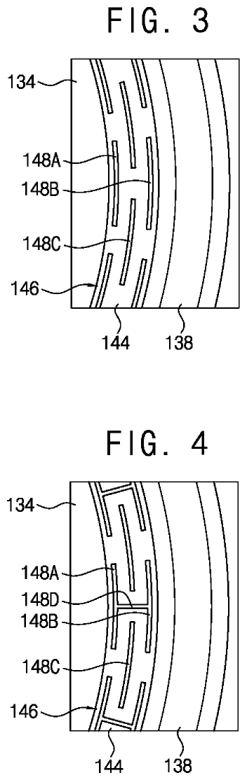

FIGS. 3 to 8 are schematic enlarged plan views illustrating examples of a ventilation path as shown in FIG. 2.

Referring to FIG. 3, the ventilation path 146 may include a plurality of inner slits 148A adjacent to the lower electrode layer 134 and extending in the circumferential direction, and a plurality of outer slits 148B adjacent to the first anchor portion 138 and extending in the circumferential direction. Further, the ventilation passage 146 may include a plurality of first intermediate slits 148C disposed between the inner slits 148A and the outer slits 148B and extending in the circumferential direction. In particular, the inner slits 148A and the outer slits 148B may be arranged to correspond to each other in a radial direction, and the first intermediate slits 148C and the inner slits 148A may be arranged to have a zigzag shape in the circumferential direction. Further, the first intermediate slits 148C and the outer slits 148B may be arranged to have a zigzag shape in the circumferential direction. Accordingly, the elastic strength of the diaphragm 132 may be reduced by the ventilation region 144, and thus the sensitivity of the MEMS microphone 100 may be improved.

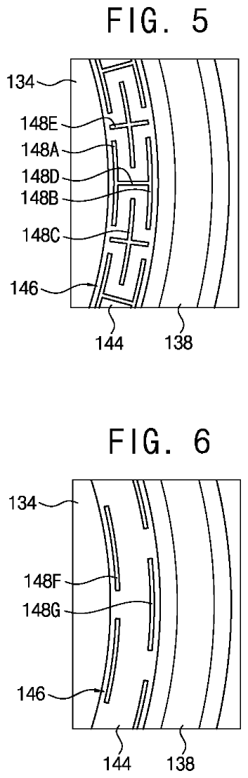

Referring to FIGS. 4 and 5, the ventilation path 146 may include second intermediate slits 148D radially extending and connecting between the inner slits 148A and the outer slits 148B. Further, the ventilation path 146 may include third intermediate slits 148E radially extending between the inner slits 148A and the outer slits 148B. In such case, the third intermediate slits 148E may be formed to cross the first intermediate slits 148C.

Referring to FIG. 6, the ventilation path 146 may include inner slits 148F adjacent to the lower electrode layer 134 and extending in the circumferential direction, and outer slits 148G adjacent to the first anchor portion 138 and extending in the circumferential direction. In such case, the inner slits 148F and the outer slits 148G may be arranged to have a zigzag shape in the circumferential direction.

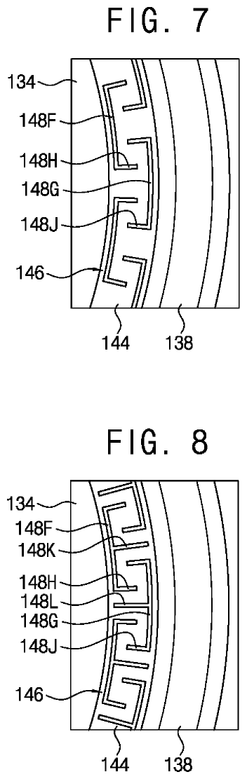

Referring to FIG. 7, the ventilation path 146 may include first extending slits 148H radially extending from ends of the inner slits 148F toward the outer slits 148G, and second extending slits 148J radially extending from ends of the outer slits 148G toward the inner slits 148F.

Referring to FIG. 8, the ventilation path 146 may include first branch slits 148K radially extending from the inner slits 148F toward the first anchor portion 138, and second branch slits 148L radially extending from the outer slits 148G toward the lower electrode layer 134.

Referring again to FIGS. 1 and 2, the diaphragm 132 may include a plurality of convex portions 136. The convex portions 136 may correspond to the air holes 194 and may protrude toward the back plate 162. In particular, as shown in FIG. 2, the convex portions 136 may protrude toward the air holes 194 of the back plate 162. For example, the convex portions 136 protrude upward from the lower electrode layer 134 and may be made of the same material as the lower electrode layer 134. As an example, the lower electrode layer 134 and the convex portions 136 may be formed of impurity-doped polysilicon.

The MEMS microphone 100 may include a first electrode pad 140 electrically connected to the lower electrode layer 134. As shown in FIG. 1, the lower electrode layer 134 and the first electrode pad 140 may be electrically connected through a first connection pattern 142. For example, the first electrode pad 140 and the first connection pattern 142 may be made of the same material as the lower electrode layer 134.

The first anchor portion 138 may be disposed on an upper surface of the substrate 102. For example, the first anchor portion 138 and the ventilation region 144 may be formed of undoped polysilicon.

The back plate 162 may include a support layer 180 made of an insulating material, and an upper electrode layer 164 attached to a lower surface of the support layer 180 and made of a conductive material. In particular, the back plate 162 may be disposed above the diaphragm 132 so that the upper electrode layer 164 is separated from the lower electrode layer 134 by a predetermined distance. For example, the upper electrode layer 164 may be formed of impurity-doped polysilicon, and the support layer 180 may be formed of silicon nitride.

The MEMS microphone 100 may include a second anchor portion 184 for fixing the back plate 162 on the substrate 102, and a second electrode pad 166 electrically connected to the upper electrode layer 164. As shown in FIG. 2, the second anchor portion 184 may be disposed on the upper surface of the substrate 102 and may be made of silicon nitride. As shown in FIG. 1, the upper electrode layer 164 and the second electrode pad 166 may be electrically connected through a second connection pattern 168. For example, the second electrode pad 166 and the second connection pattern 168 may be made of the same material as the upper electrode layer 164.

The first anchor portion 138 may have a circular ring shape surrounding the cavity 104, and the second anchor portion 184 may have a circular ring shape surrounding the first anchor portion 138.

A lower insulating layer 120 may be disposed on the upper surface of the substrate 102, and an upper insulating layer 150 may be disposed on the lower insulating layer 120. In such case, the first electrode pad 140 may be disposed on the lower insulating layer 120, and the second electrode pad 166 may be disposed on the upper insulating layer 150. For example, the lower insulating layer 120 and the upper insulating layer 150 may be made of silicon oxide and may be formed to surround the second anchor portion 184.

A first bonding pad 190 may be disposed on the first electrode pad 140 through the upper insulating layer 150 and the support layer 180, and a second bonding pad 192 may be disposed on the second electrode pad 166 through the supporting layer 180. In addition, the support layer 180 may include protrusions 182 extending downward through the upper electrode layer 164. The protrusions 182 may be made of the same material as the support layer 180 and may be used to prevent the lower electrode layer 134 and the upper electrode layer 164 from contacting each other.

In accordance with an embodiment of the present disclosure, each of the convex portions 136 may have a hollow truncated cone or hollow truncated pyramid shape. In particular, each of the convex portions 136 may have an upper inclined surface 136A adjacent to a lower edge portion of each of the air holes 194. As a result, the area of the lower electrode layer 134 may be increased, and thus the capacitance of the MEMS microphone 100 may be increased, and the sensitivity of the MEMS microphone 100 may be improved.

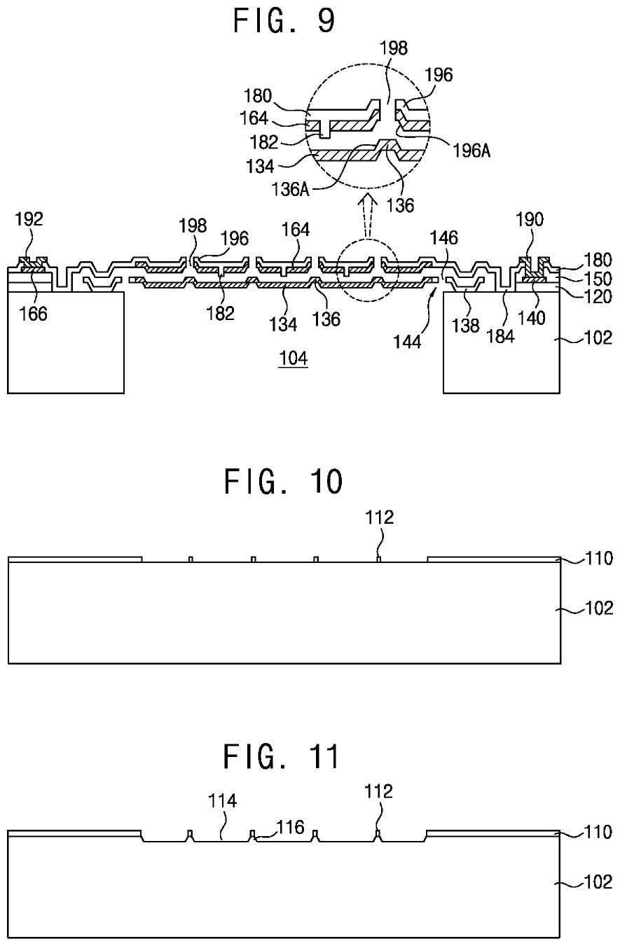

FIG. 9 is a schematic cross-sectional view illustrating a MEMS microphone in accordance with another embodiment of the present disclosure.

Referring to FIG. 9, the back plate may include a plurality of second convex portions 196 formed to surround air holes 198, respectively, and protruding in the same direction as the convex portions 136. Each of the second convex portions 196 may have a hollow truncated cone or hollow truncated pyramid shape, and may have a lower inclined surface 196A corresponding to the upper inclined surface 136A of the convex portions 136. In such case, each of the air holes 198 may be formed to pass through an upper portion of each of the second convex portions 196.

As a result, the area of the upper electrode layer 164 may be increased, and thus the capacitance of the MEMS microphone 100 may be increased, and the sensitivity of the MEMS microphone 100 may be improved.

FIGS. 10 to 24 are schematic cross-sectional views illustrating a method of manufacturing the MEMS microphone as shown in FIG. 2.

Referring to FIG. 10, a mask layer 110 for forming a diaphragm 132 may be formed on a substrate 102. For example, the mask layer 110 may be made of silicon oxide and may include patterns 112 corresponding to convex portions 136 of the diaphragm 132. For example, after forming a silicon oxide layer (not shown) on the substrate 102 through a thermal oxidation process or a chemical vapor deposition process, a photoresist pattern (not shown) may be formed on the silicon oxide layer. Then, the mask layer 110 may be formed from the silicon oxide layer by performing an anisotropic etching process using the photoresist pattern as an etching mask. After forming the mask layer 110, the photoresist pattern may be removed through a stripping process and/or an ashing process.

Referring to FIG. 11, a surface portion of the substrate 102 may be partially removed by performing an etching process using the mask layer 110 as an etching mask. For example, a single crystal silicon substrate may be used as the substrate 102, and the surface portion of the substrate 102 may be removed by wet etching process. In particular, a recess 114 having a plurality of protrusions 116 may be formed in the surface portion of the substrate 102 by the wet etching process. The protrusions 116 may have inclined side surfaces due to a difference in etching rate according to the crystal direction of the substrate 102. For example, the surface portion of the substrate 102 may be partially removed through wet etching using an aqueous solution of potassium hydroxide (KOH) as an etchant. In addition, although not shown, after forming the recess 114, the mask layer 110 may be removed through an etching process.

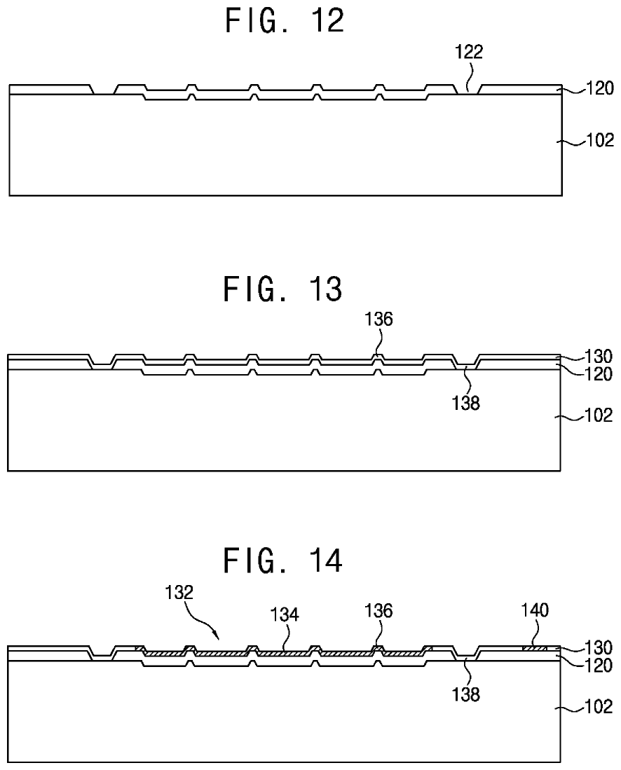

Referring to FIG. 12, a lower insulating layer 120 may be formed on the substrate 102. For example, the lower insulating layer 120 may include silicon oxide and may be formed conformally, that is, to have a substantially uniform thickness through a chemical vapor deposition process. Then, a first anchor channel 122 having a circular ring shape surrounding the recess 114 may be formed by patterning the lower insulating layer 120. For example, after forming a photoresist pattern exposing a portion where the first anchor channel 122 is to be formed on the lower insulating layer 120, the first anchor channel 122 exposing a portion of an upper surface of the substrate 102 may be formed by performing an etching process using the photoresist pattern as an etching mask.

Referring to FIG. 13, a lower silicon layer 130 may be conformally formed on the lower insulating layer 120 to have a substantially uniform thickness. For example, the lower silicon layer 130 may be a polysilicon layer formed through a chemical vapor deposition process. In particular, a portion of the lower silicon layer 130 formed in the first anchor channel 122 may be used as a first anchor portion 138 for fixing a diaphragm 132 to be formed subsequently on the substrate 102. Further, convex portions 136 protruding upward may be formed in the lower silicon layer 130 by the protruding portions 116 in the recess 114.

Referring to FIG. 14, a portion of the lower silicon layer 130 may be formed into a lower electrode layer 134 having conductivity by performing an ion implantation process. In addition, a first electrode pad 140 and a first connection pattern 142 (refer to FIG. 1) for connecting the lower electrode layer 134 and the first electrode pad 140 may be formed in the lower silicon layer 130 by the ion implantation process. In particular, a portion of the lower silicon layer 130 including the convex portions 136 may be formed into the lower electrode layer 134, and thus the convex portions 136 may function as a part of the lower electrode layer 134.

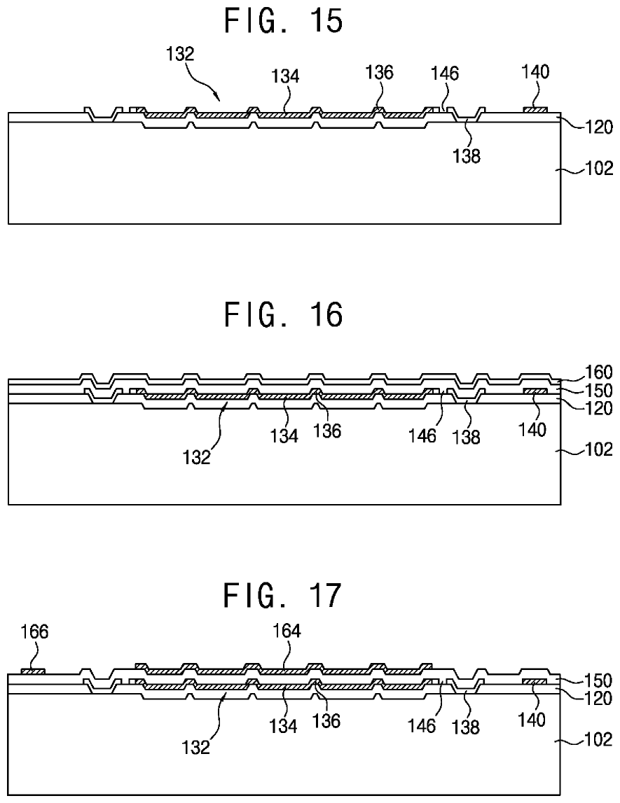

Referring to FIG. 15, the lower silicon layer 130 may be patterned so that a diaphragm 132 including the lower electrode layer 134, the first electrode pad 140, and the first connection pattern 142 remain on the lower insulating layer 120. Further, the first anchor portion 138 for fixing the diaphragm 132 on the substrate 102 may be formed on the portion of the substrate 102 exposed by the first anchor channel 122 by patterning the lower silicon layer 130. In particular, a portion of the lower silicon layer 130 between the lower electrode layer 134 and the first anchor portion 138 may function as a ventilation region 144, and a ventilation path 146 including a plurality of slits may be formed through the ventilation region 144 by patterning the lower silicon layer 130. For example, after forming a photoresist pattern for forming the diaphragm 132, the first anchor portion 138, the first electrode pad 140, the first connection pattern 142, and the ventilation path 146 on the lower silicon layer 130, an etching process using the photoresist pattern as an etching mask may be performed until the lower insulating layer 120 is exposed.

Referring to FIG. 16, an upper insulating layer 150 may be formed on the diaphragm 132, the first anchor portion 138, the first electrode pad 140, the first connection pattern 142, and the lower insulating layer 120. For example, the upper insulating layer 150 may include silicon oxide and may be formed conformally to have a substantially uniform thickness through a chemical vapor deposition process. Subsequently, an upper silicon layer 160 may be conformally formed on the upper insulating layer 150 to have a substantially uniform thickness. For example, the upper silicon layer 160 may be a polysilicon layer formed through a chemical vapor deposition process.

Referring to FIG. 17, an ion implantation process may be performed to form the upper silicon layer 160 into a conductive layer (not shown), that is, a polysilicon layer doped with impurities. The conductive layer may be patterned to form an upper electrode layer 164 corresponding to the lower electrode layer 134, a second electrode pad 166, and a second connection pattern 168 (refer to FIG. 1) for connecting the upper electrode layer 164 and the second electrode pad 166. That is, remaining portions of the conductive layer other than the upper electrode layer 164, the second electrode pad 166, and the second connection pattern 168 may be removed. For example, after forming a photoresist pattern on the conductive layer to expose portions of the conductive layer except for portions where the upper electrode layer 164, the second electrode pad 166, and the second connection pattern 168 are to be formed, an etching process using the photoresist pattern as an etching mask may be performed until the upper insulating layer 150 is exposed.

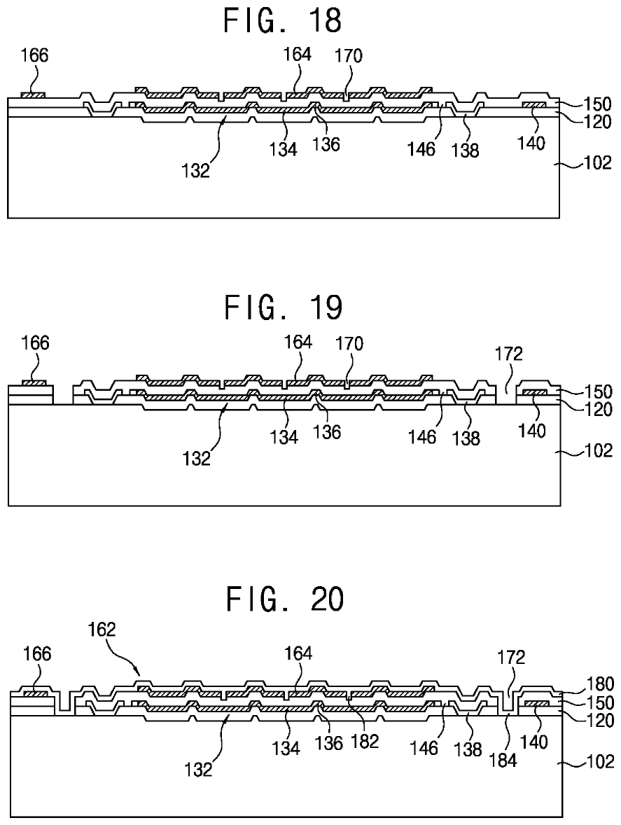

Referring to FIG. 18, a plurality of holes 170 for forming protrusions 182 (refer to FIG. 2) extending toward the lower electrode layer 134 may be formed by removing portions of the upper electrode layer 164 and the upper insulating layer 150. The holes 170 may have a predetermined depth extending into the upper insulating layer 150 through the upper electrode layer 164. For example, after forming a photoresist pattern exposing portions of the upper electrode layer 164 where the holes 170 are to be formed, an anisotropic etching process using the photoresist pattern as an etching mask may be performed for a predetermined time.

Referring to FIG. 19, the upper insulating layer 150 and the lower insulating layer 120 may be patterned to form a second anchor channel 172 having a circular ring shape surrounding the first anchor portion 138. For example, after forming a photoresist pattern exposing portions of the upper insulating layer 150 where the second anchor channel 172 is to be formed, an anisotropic etching process using the photoresist pattern as an etching mask may be performed until the upper surface of the substrate 102 is exposed.

Referring to FIG. 20, after forming the second anchor channel 172, a support layer 180 may be conformally formed on the upper electrode layer 164 and the upper insulating layer 150 to have a substantially uniform thickness. As a result, a back plate 162 including the upper electrode layer 164 and the support layer 180 may be formed on the substrate 102. For example, the support layer 180 may be a silicon nitride layer formed by a chemical vapor deposition process. In particular, the support layer 180 may be formed to fill the holes 170, and thus the protrusions 182 extending downward from the support layer 180 through the upper electrode layer 164 may be formed. In addition, a portion of the support layer 180 formed in the second anchor channel 172 may be used as a second anchor portion 184 for fixing the support layer 180 on the substrate 102.

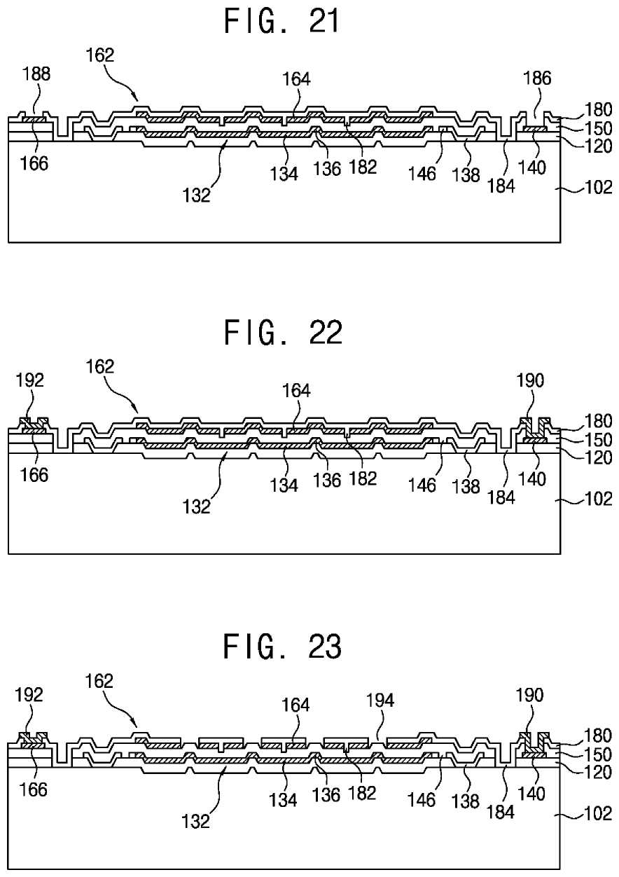

Referring to FIG. 21, a first opening 186 and a second opening 188 may be formed to expose the first electrode pad 140 and the second electrode pad 166, respectively, by patterning the support layer 180 and the upper insulating layer 150. For example, after forming a photoresist pattern exposing portions of the support layer 180 corresponding to the first electrode pad 140 and the second electrode pad 166, the first opening 186 and the second opening 188 may be formed through an anisotropic etching process using the photoresist pattern as an etching mask.

Referring to FIG. 22, a first bonding pad 190 and a second bonding pad 192 may be formed on the first electrode pad 140 and the second electrode pad 166, respectively. For example, the first bonding pad 190 and the second bonding pad 192 may be made of metal such as aluminum and may be formed by forming an aluminum layer on the support layer 180 and then patterning the aluminum layer.

Referring to FIG. 23, a plurality of air holes 194 may be formed by patterning the support layer 180 and the upper electrode layer 164. In particular, the air holes 194 may be formed to correspond to the convex portions 136, respectively. For example, after forming a photoresist pattern exposing portions of the supporting layer 180 where the air holes 194 are to be formed, the air holes 194 may be formed through an anisotropic etching process using the photoresist pattern as an etching mask.

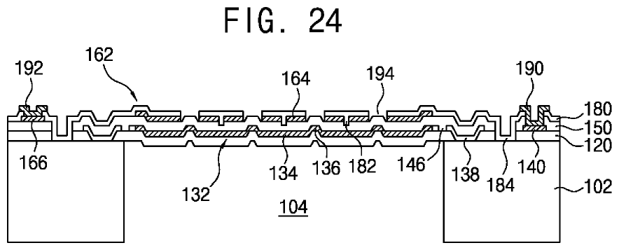

Referring to FIG. 24, a back grinding process for reducing the thickness of the substrate 102 may be performed, and a cavity 104 penetrating the substrate 102 may then be formed. The cavity 104 may be formed to correspond to the diaphragm 132 by an anisotropic etching process.

Referring again to FIG. 2, after forming the cavity 104, a portion of the lower insulating layer 120 and a portion of the upper insulating layer 150 formed inside the second anchor portion 184 may be removed through a wet etching process. In such case, while the wet etching process is performed, the etchant may be supplied between the diaphragm 132 and the back plate 162 through the air holes 194 and the ventilation path 146.

As another example, as shown in FIG. 9, the back plate 162 may include second convex portions 196 formed by the convex portions 136, and air holes 198 may be formed through upper portions of the second convex portions 196.

In accordance with the embodiments of the present disclosure as described above, the ventilation path 146 including the plurality of slits may be formed in the ventilation region 144. Accordingly, the elastic strength of the diaphragm 132 may be reduced, thereby improving the sensitivity of the MEMS microphone 100. Further, the diaphragm 132 may include the convex portions 136 corresponding to the air holes 194 formed through the back plate 162, thereby increasing an area of the lower electrode layer 134. In addition, the back plate 162 may include the second convex portions 196 corresponding to the convex portions 136, thereby increasing an area of the upper electrode layer 164. As a result, the capacitance of the MEMS microphone 100 may be increased, and thus the sensitivity of the MEMS microphone 100 may be significantly improved.

Although the example embodiments of the present disclosure have been described with reference to the specific embodiments, they are not limited thereto. Therefore, it will be readily understood by those skilled in the art that various modifications and changes can be made thereto without departing from the spirit and scope of the present disclosure defined by the appended claims.

1. A MEMS microphone comprising:
a substrate having a cavity;
a diaphragm disposed above the cavity and having a ventilation path; and
a back plate disposed above the diaphragm and having a plurality of air holes,
wherein the ventilation path comprises a plurality of slits extending in a circumferential direction.

2. The MEMS microphone of claim 1, further comprising:
a first anchor portion configured to surround the diaphragm and fixing the diaphragm on the substrate,
wherein the diaphragm comprises:
a lower electrode layer made of a conductive material; and
a ventilation region disposed between the lower electrode layer and the first anchor portion and through which the slits are formed.

3. The MEMS microphone of claim 2, wherein the ventilation path comprises:
inner slits adjacent to the lower electrode layer and extending in the circumferential direction; and
outer slits adjacent to the first anchor portion and extending in the circumferential direction.

4. The MEMS microphone of claim 3, wherein the ventilation path further comprises:
first intermediate slits disposed between the inner slits and the outer slits and extending in the circumferential direction.

5. The MEMS microphone of claim 4, wherein the ventilation path further comprises:
second intermediate slits radially extending and connecting between the inner slits and the outer slits.

6. The MEMS microphone of claim 5, wherein the ventilation path further comprises:
third intermediate slits radially extending between the inner slits and the outer slits.

7. The MEMS microphone of claim 3, wherein the ventilation path further comprises:
first extending slits radially extending from ends of the inner slits toward the outer slits; and
second extending slits radially extending from ends of the outer slits toward the inner slits.

8. The MEMS microphone of claim 7, wherein the ventilation path further comprises:
first branch slits radially extending from the inner slits toward the first anchor portion; and
second branch slits radially extending from the outer slits toward the lower electrode layer.

9. The MEMS microphone of claim 1, wherein the diaphragm comprises a plurality of convex portions respectively corresponding to the air holes and protruding toward the back plate.

10. The MEMS microphone of claim 9, wherein each of the convex portions has a hollow truncated cone or hollow truncated pyramid shape.

11. The MEMS microphone of claim 9, wherein the back plate comprises a plurality of second convex portions configured to surround the air holes, respectively, and protruding in a same direction as the convex portions.

12. The MEMS microphone of claim 11, wherein each of the convex portions has an upper inclined surface, and each of the second convex portions has a lower inclined surface corresponding to the upper inclined surface.

13. A method of manufacturing a MEMS microphone, the method comprising:
forming a diaphragm having a ventilation path on a substrate;
forming a back plate having a plurality of air holes above the diaphragm; and
forming a cavity exposing the diaphragm through the substrate,
wherein the ventilation path comprises a plurality of slits extending in a circumferential direction.

14. The method of claim 13, wherein forming the diaphragm comprises:
forming a lower insulating layer on the substrate;
partially removing the lower insulating layer to form a first anchor channel partially exposing the substrate;
forming a lower silicon layer on the lower insulating layer and the first anchor channel;
performing an ion implantation process to form a portion of the lower silicon layer into a lower electrode layer; and
patterning the lower silicon layer to form the diaphragm and the ventilation path,
wherein the lower silicon layer is patterned so that the diaphragm comprises the lower electrode layer.

15. The method of claim 14, wherein a portion of the lower silicon layer formed in the first anchor channel functions as a first anchor portion for fixing the diaphragm on the substrate, and the lower silicon layer is patterned so that the first anchor portion remains in the first anchor channel.

16. The method of claim 13, wherein the ventilation path is formed through a ventilation region disposed between the lower electrode layer and the first anchor portion.

17. The method of claim 14, wherein the diaphragm is formed to comprise a plurality of convex portions respectively corresponding to the air holes and protruding toward the back plate.

18. The method of claim 17, wherein forming the diaphragm further comprises:
forming a mask layer on the substrate to cover portions where the convex portions are to be formed;
performing an etching process using the mask layer as an etching mask to partially remove a surface portion of the substrate; and
removing the mask layer,
wherein the lower insulating layer is formed on the substrate after the mask layer is removed.

19. The method of claim 14, wherein forming the back plate comprises:
forming an upper insulating layer on the diaphragm;
forming an upper silicon layer on the upper insulating layer;
performing an ion implantation process to form a portion of the upper silicon layer into an upper electrode layer;
removing another portion of the upper silicon layer to expose a portion of the upper insulating layer; and
forming a support layer for supporting the upper electrode layer on the upper electrode layer and the exposed portion of the upper insulating layer.

20. The method of claim 19, wherein forming the back plate further comprises:
partially removing the upper insulating layer and the lower insulating layer to form a second anchor channel partially exposing the substrate,
wherein a portion of the support layer formed in the second anchor channel functions as a second anchor portion for fixing the back plate on the substrate.
